(19) United States
(12) Patent Application Publication
(10) Pub. No.: US 2007/0064844 A1
(43) Pub. Date: Mar. 22, 2007

(54) Method to attenuate specific signal components within a data signal

(76) Inventor: Michael R. May, Austin, TX (US)

Correspondence Address: GARLICK HARRISON & MARKISON, P.O. BOX 160727, AUSTIN, TX, 78716-0727, US

(21) Appl. No.: 11/233,081

(22) Filed: Sep. 22, 2005

(51) Int. Cl. H03D 1/04

(52) U.S. Cl. 375/346

(57) ABSTRACT

The present invention provides a method for attenuating specific signal components within a digital data signal. Such data components may include timing components such as pilot tones and their multiples. This process first receives a decoded data signal. A modulo processing operation, such as a multi-tapped integration, a leaky bucket integration, or other like averaging function on every N^{th} sample of the received data signal, is then performed to produce a representation of the signal component to be attenuated. A scaling factor may be applied to the representation before subtracting the representation of the signal component to be attenuated from the received data signal. Scaling is required because the signal components to be attenuated may lack a predetermined amplitude or exhibit a time varying amplitude. Subtracting the scaled representation of the signal component to be attenuated from the received data signal produces a filtered data signal wherein the filtering process may exhibit a deep and well defined filter.

### TECHNICAL FIELD OF THE INVENTION

The present invention relates generally to portable handheld digital audio systems and more particularly to integrated circuits within a handheld audio system.

### BACKGROUND OF THE INVENTION

As is known, handheld digital audio systems are becoming very popular. Such systems include digital audio players/recorders that record and subsequently playback MP3 files, WMA files, etc. Such digital audio players/recorders may also be used as digital dictaphones and file transfer devices. Further expansion of digital audio players/recorders includes providing a radio receiver such that the device offers frequency modulation (FM) or amplitude modulation (AM) radio reception.

While digital audio players/recorders are increasing their feature sets, the increase in feature sets has been done in a less than optimal manner. For instance, with the inclusion of an FM receiver in a digital audio player/recorder, the FM receiver is a separate integrated circuit (IC) from the digital audio player/recorder chip set, or IC. As such, the FM receiver IC functions completely independently of the digital audio player/recorder IC, even though both ICs include common functionality.

Four papers teach FM receivers that address at least one of the above mentioned issues. The four papers include, “A 10.7-MHz IF-to-Baseband Sigma-Delta A/D Conversion System for AM/FM Radio Receivers” by Eric Van Der Zwan, et. al. IEEE Journal of Solid State Circuits, VOL. 35, No. 12, December 2000; “A fully Integrated High-Performance FM Stereo Decoder” by Gregory J. Manlove et. al, IEEE Journal of Solid State Circuits, VOL. 27, No. 3, March 1992; “A 5-MHz IF Digital FM Demodulator”, by Jaejin Park et. al, IEEE Journal of Solid State Circuits, VOL. 34, No. 1, January 1999; and “A Discrete-Time Bluetooth Receiver in a 0.13 μm Digital CMOS Process”, by K. Muhammad et. al, ISSCC2004/Session 15/Wireless Consumer ICs/15.1, 2004 IEEE International Solid-State Circuit Conference.

While the prior art has provided FM decoders, a need still exists for a method and apparatus of radio decoding that is optimized to function with a digital audio player/recorder to produce an optimized handheld audio system.

### BRIEF DESCRIPTION OF THE DRAWINGS

FIG. 1 is a schematic block diagram of a handheld audio system in accordance with the present invention;

FIG. 2 is a schematic block diagram of a radio signal decoder IC in accordance with the present invention;

FIG. 3 is a schematic block diagram of a radio signal decoder in accordance with the present invention;

FIG. 4 is a frequency spectrum diagram of a digital radio composite signal in accordance with the present invention;

FIG. 5 is a diagram of an example of error correction in accordance with the present invention;

FIG. 6 is a logic diagram illustrating the functionality of an error sensing module in accordance with the present invention;

FIG. 7 is a schematic block diagram of an pilot tracking module in accordance with the present invention;

FIG. 8 is a schematic block diagram of a tone cancellation module in accordance with an embodiment of the present invention;

FIG. 9 is a schematic block diagram of a single stage modulo processing module in accordance with an embodiment of the present invention;

FIG. 10 is a schematic block diagram of a single stage modulo processing module in accordance with an embodiment of the present invention;

FIG. 11 is a schematic block diagram of a multi-order modulo processing module in accordance with an embodiment of the present invention;

FIG. 12 is a logic flow diagram in accordance with an embodiment of the present invention; and

FIG. 13 is a logic flow diagram in accordance with an embodiment of the present invention.

### DETAILED DESCRIPTION OF THE INVENTION

Preferred embodiments of the present invention are illustrated in the FIGS., like numerals being used to refer to like and corresponding parts of the various drawings.

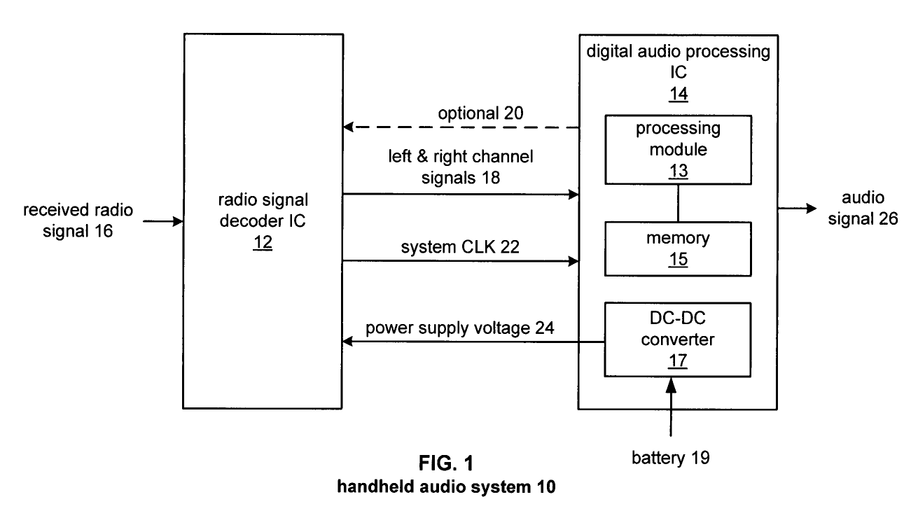

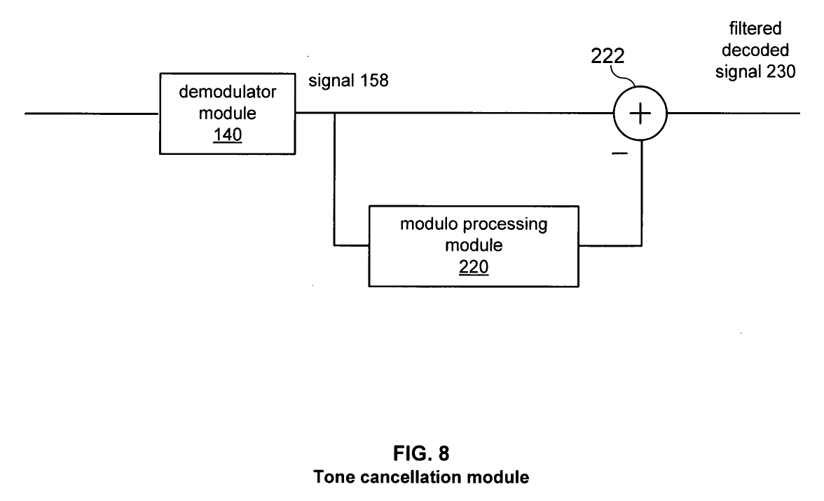

FIG. 1 is a schematic block diagram of a handheld audio system 10 that includes radio signal decoder integrated circuit (IC) 12 and digital audio processing IC 14. Digital audio processing IC 14 includes processing module 13, memory 15, and DC-DC converter 17. Processing module 13 may be a single processing device or a plurality of processing devices. Such a processing device may be a microprocessor, micro-controller, digital signal processor, microcomputer, central processing unit, field programmable gate array, programmable logic device, state machine, logic circuitry, analog circuitry, digital circuitry, and/or any device that manipulates signals (analog and/or digital) based on operational instructions. Memory 15 may be a single memory device or a plurality of memory devices. Such a memory device may be a read-only memory, random access memory, volatile memory, non-volatile memory, static memory, dynamic memory, flash memory, cache memory, and/or any device that stores digital information. Note that when processing module 13 implements one or more of its functions via a state machine, analog circuitry, digital circuitry, and/or logic circuitry, the memory storing the corresponding operational instructions may be embedded within, or external to, the circuitry comprising the state machine, analog circuitry, digital circuitry, and/or logic circuitry. Further note that, memory 15 stores, and processing module 13 executes, operational instructions corresponding to at least some of the steps and/or functions illustrated in FIGS. 8-13.

When a power source, such as battery 19, is initially applied to digital audio processing IC 14, DC-DC converter 17 generates a power supply voltage 24 based on an internal oscillation. When power supply voltage 24 reaches a desired value such that radio signal decoder 12 can operate, radio signal decoder IC 12 generates system clock 22; with the remaining functionality of radio signal decoder IC 12 being inactive awaiting a second enable signal or being activated once system clock 22 is functioning. Radio signal decoder IC 12 provides system clock 22 to digital audio processing IC 14. Upon receiving system clock 22, the DC-DC converter may switch from the internal oscillation to system clock 22 to produce power supply voltage 24 from V-battery 19, or an external power source. Note that when a portion of radio signal decoder IC 12 is powered via the battery 19, radio signal decoder IC 12 may produce a real time clock (RTC) in addition to producing system clock 22. Radio signal decoder IC 12 may be directly coupled to or coupled via switches to battery 19.

With system clock 22 functioning, radio signal decoder IC 12 converts received radio signal 16 into left and right channel signals 18, which may be analog or digital signals. In one embodiment, left and right channel signals 18 include a Left plus Right (LPR) signal, and a Left Minus Right (LMR) signal. Radio signal decoding IC 12 provides these left and right channel signals to digital audio processing IC 14.

Digital audio processing IC 14, which may be a digital audio player/recorder IC such as the STMP35XX and/or the STMP36XX digital audio processing system IC manufactured and distributed by Sigmatel Incorporated, receives left and right channel signals 18 and produces there from audio signals 26. Digital audio processing IC 14 may provide audio signals 26 to a headphone set or other type of speaker output. As an alternative to producing audio signals 26 from left and right channel signals 18, digital audio processing IC 14 process stored files, such as but not limited to MP3 files, WMA files, and/or other digital audio files to produce audio signals 26.

A digital radio interface may be used to communicatively couple digital audio processing IC 14 to radio signal decoder IC 12. Such a digital radio interface may generate a data clock of 4 MHz, 6 MHz, or some other rate, in order to support the conveyance of serial data between ICs 12 and 14. In addition, such a digital radio interface formats the data into a packet, or frame, which may include one to five data words having a sampling rate based on the sample rate conversion (SRC) of radio signal decoder IC 12, which will be described in greater detail. Nominally, a packet, or frame, will include four 18-bit words having a sampling rate of at 44.1 KHz per word, 2 of the 18 bits are for control information and the remaining 16 bits are for data.

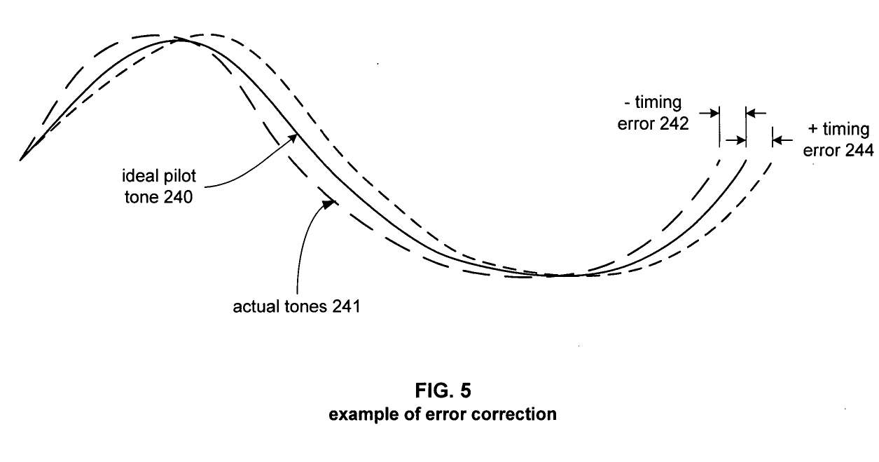

The digital radio interface may convey more than left and right channel signals 18, which may be in the form of LPR channel signals and LMR channel signals. For instance, such a digital radio interface may convey receive signal strength indications, data clock rates, control information, functionality enable/disable signals, functionality regulation and/or control signals, and radio data service signals between ICs 12 and 14. All of these components may be contained within a composite signal, such as the composite signal described with reference to FIG. 5.

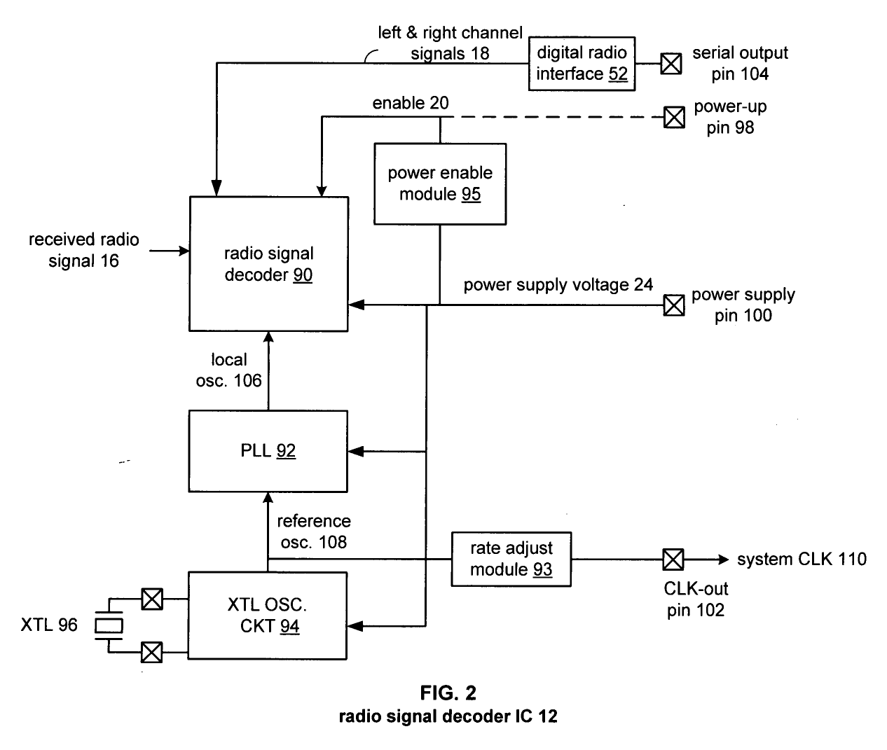

FIG. 2 is a schematic block diagram of an embodiment of radio signal decoder IC 12 that includes digital radio interface 52, crystal oscillation circuit (XTL OSC CKT) 94, PLL 92, and radio signal decoder 90. Crystal oscillation circuit 94 is operably coupled to external crystal 96 to produce reference oscillation 108. The rate of reference oscillation 108 is based on the properties of external crystal 96 and, as such, may range from a few kilo-Hertz to hundreds of mega-Hertz. In an embodiment, reference oscillation 108 produces system output clock 110, which is outputted via a clock output (CLK_out) pin 102. As the reader will appreciate, system clock 110 may be identical to reference oscillation 108, may have a rate that is a multiple of reference oscillation 108 via rate adjust module 93, may have a rate that is a fraction of reference oscillation 108 via rate adjust module 93, may have a phase shift with respect to the reference oscillation, or a combination thereof.

PLL 92 also produces local oscillation 106 from reference oscillation 108. The rate of the local oscillation corresponds to a difference between an intermediate frequency (IF) and a carrier frequency of received radio signal 16. For instance, if the desired IF is 2 MHz and the carrier frequency of received radio signal 16 is 101.5 MHz, the local oscillation is 99.5 MHz (i.e., 101.5 MHz-2 MHz). As the reader will appreciate, the IF may range from DC to a few tens of MHz and the carrier frequency of received radio signal 16 is dependent upon the particular type of radio signal (e.g., AM, FM, satellite, cable, etc.). Radio signal decoder 90 may process a high side carrier or a low side carrier of the RF signals and/or IF signals.

Radio signal decoder 90 converts received radio signal 16, which may be an AM radio signal, FM radio signal, satellite radio signal, cable radio signal, into left and right channel signals 18 with local oscillation 106. Radio signal decoder 90, provides the left and right channel signals to digital radio interface 52 for outputting via a serial output pin 104. Serial output pin 104 may includes one or more serial input/output connections. As is further shown, radio signal decoder 90 may receive an enable signal and a power supply voltage from power supply pin 100. Alternatively, a power enable module may generate an enable signal when power supply 24 reaches a desired value.

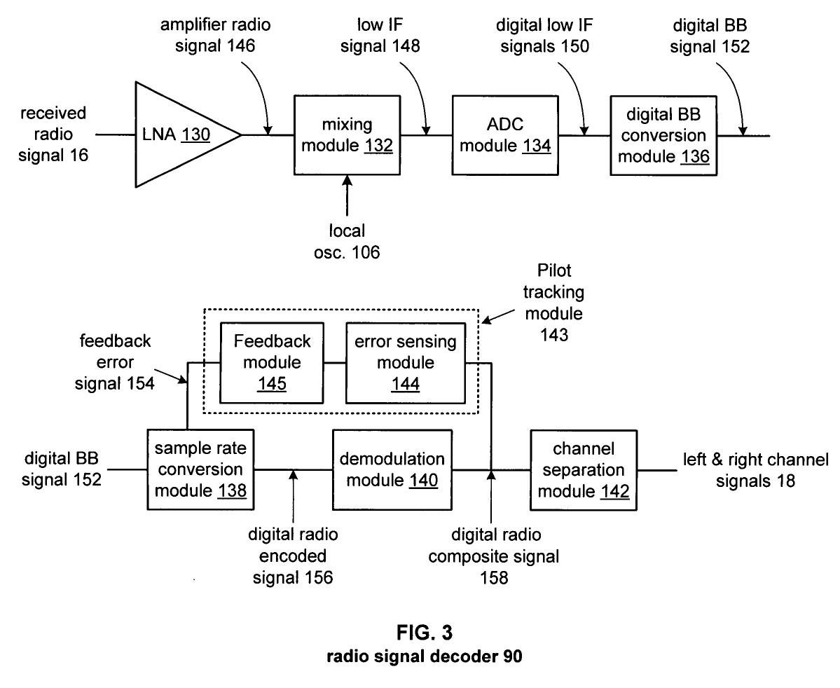

FIG. 3 is a schematic block diagram of a radio signal decoder 90 that includes a low noise amplifier (LNA) 130, mixing module 132, analog-to-digital conversion (ADC) module 134, digital baseband conversion module 136, SRC module 138, demodulation module 140, channel separation module 142, and a pilot tracking module 143 that further includes error sensing module 144 and feedback module 145. In operation, LNA 130 receives radio signal 16 and amplifies radio signal 16 to produce an amplified radio signal 146. The gain at which LNA 130 amplifies receive signal 16 is dependent on the magnitude of received radio signal 16 and automatic gain control (AGC) functionality of radio signal decoder 90. Mixing module 132 mixes amplified radio signal 146 with local oscillation 106 to produce a low IF signal 148. If local oscillation 106 has a frequency that matches the carrier frequency of radio signal 146 low IF signal 148 will have a carrier frequency of approximately zero. If local oscillation 106 is slightly more or less than radio signal 146, then low IF signal 148 will have a carrier frequency based on the difference between the frequency of radio signal 146 and the frequency of local oscillation 106. In such a situation, the carrier frequency of low IF signal 148 may range from 0 hertz to tens of mega-Hertz.

ADC module 134 converts low IF signal 148 into a digital low IF signal 150. In one embodiment, low IF signal 148 is a complex signal including an in-phase component and a quadrature component. Accordingly, ADC module 134 converts the in-phase and quadrature components of low IF signal 148 into corresponding in-phase and quadrature digital signals 150.

Digital baseband conversion module 136 is operably coupled to convert digital low IF signals 150 into digital baseband signals 152. Note that if digital low IF signals 150 have a carrier frequency of approximately zero, digital baseband conversion module 136 primarily functions as a digital filter to produce digital baseband signals 152. If, however, the IF is greater than zero, digital baseband conversion module 136 functions to convert digital low IF signals 150 to have a carrier frequency of zero and performs digital filtering.

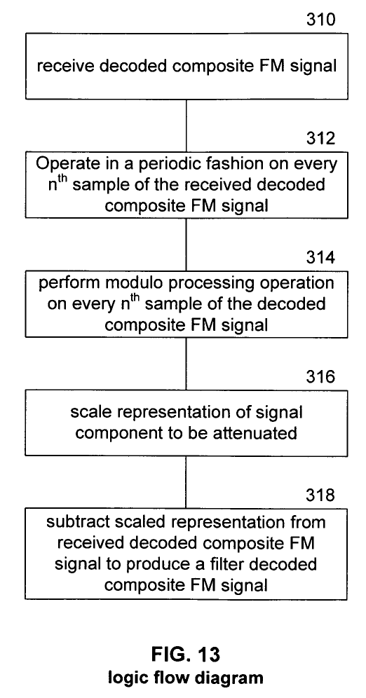

SRC module 138, which will be described in greater detail with reference to FIG. 13, receives digital baseband signal 152 and a feedback error signal 154 to produce a digital radio encoded signal 156. The digital baseband signal may be associated with a first time domain such as a time domain associated with the receiver. The digital radio encoded signal (output of the SRC module) may be associated with a second time domain such as that of the transmitter associated with the received radio signal. For example, the digital baseband signal may have a sampling rate of 400 KHz and the rate adjusted encoded signal (digital radio encoded signal 156) may have a sampling rate of 152 KHz or 228 KHz. Demodulation module 140 demodulates digital radio encoded signal 156 to produce a digital radio composite signal 158. Error sensing module 144 interprets radio signal composite signal 158 to produce an input to feedback module 145 which in turn produces feedback error signal 154. This may involve performing a pilot tracking function associated with a pilot tone within the composite signal. Channel separation module 142 is operably coupled to produce left and right channel signals 18 from digital radio composite signal 158.

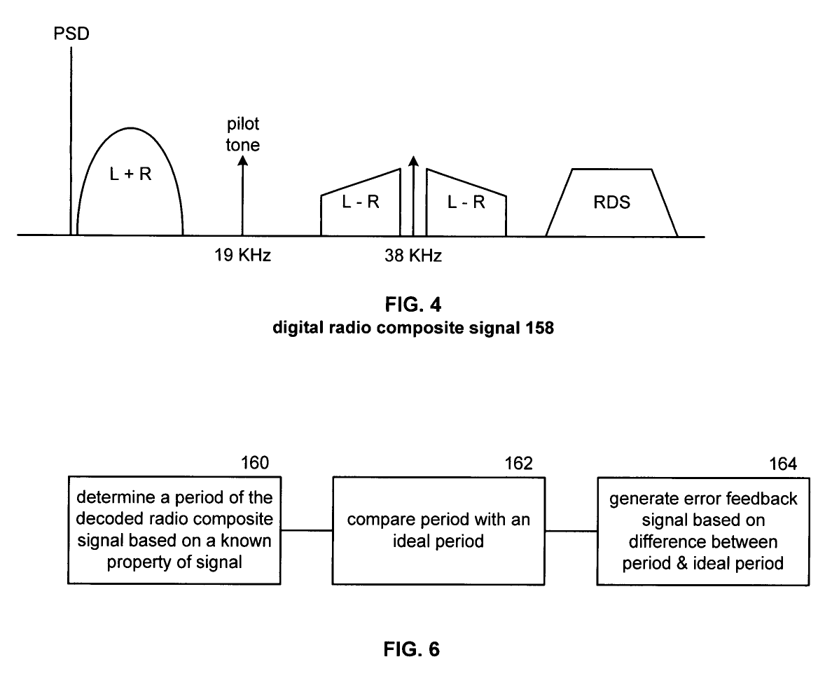

FIG. 4 is a frequency diagram of received radio signal 16, which in this embodiment is shown as composite signal 158 used to carry stereophonic audio under a pilot-tone multiplex system. A pilot-tone multiplex system multiplexes the left and right audio signal channels in a manner compatible with mono sound, using a sum-and-difference technique to produce a “mono-compatible” composite signal. Signal 16 includes a pilot tone having known properties, in some embodiments this pilot tone is located at 19 kHz and another tone is located at 38 kHz. The tone cancellation module provided by embodiments of the present invention may cancel (or attenuate) these tones and other like known components within composite signal 158. This ability to cancel such tones will depend on a well defined ability to track these tones as will be discussed with reference to FIGS. 3 and 5 through 7. Signal 16 also includes a low frequency “sum” or LPR signal component, a higher frequency “difference” or LMR signal component, and may include a radio data system (RDS) signal component. LPR signal component includes mono signal information, and LMR signal component includes stereo signal information. LMR signal component, as shown, is modulated on the 38 kHz suppressed subcarrier to produce a double sideband suppressed carrier signal (DSBCS). The RDS signal component contains small amounts of digital information. Such digital information may include time and radio station identification, and uses a sub-carrier tone at 57 kHz to carry data at 1187.5 bits-per-second.

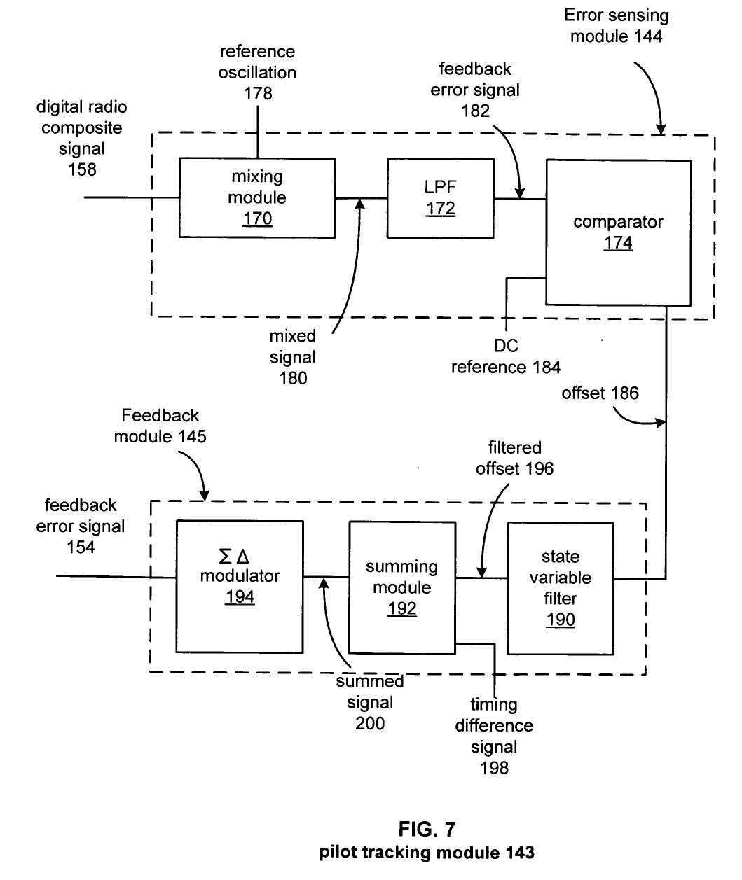

Returning to FIG. 3, pilot tracking module 143 utilizes the known properties of the 19 KHz pilot tone and the corresponding properties of the actual pilot tone (timing component) embedded within digital composite radio signal 158 to determine error feedback signal 154. In such an embodiment, SRC module 138 removes errors due to process variation, temperature variations, crystal make tolerance, et cetera from digital baseband signals 152 prior to demodulation via feedback to an interpolation module. A linear interpolator may be implemented using a linear SRC module, such as SRC module 138 of FIG. 3, and sigma-delta modulator, such as sigma-delta modulator 194 of FIG. 7. As such, the demodulation errors of prior art embodiments are avoided by correcting this signal prior to demodulation by demodulation module 140.

FIG. 5 is an example of the functionality of error correction performed by a pilot tracking module 143, SRC module 138 and demodulation module 140. In this illustration, a reference pilot tone 240 is shown as a solid line while actual pilot tone measurements 241 are indicated by dashed lines. Error sensing module 144 determines a timing error 242 or 244 of actual (measured) pilot tone signal 241, which corresponds to a timing component within digital radio signal 158, with respect to a digitized reference oscillation (reference pilot tone signal 240). Feedback error signal 154 corresponds to the timing error such that SRC module 138 adjusts the SRC based on the timing error, thereby substantially eliminating timing errors prior to decoding.

FIG. 6 is a logic diagram generally illustrating the functionality of the error sensing module. The processing of the error sensing module begins at Step 160 where it determines a period of the decoded radio composite signal based on a known property of the signal such as a pilot tone (e.g., 19 KHz or 38 KHz) or other like timing component. The processing then proceeds to Step 162 where the error sensing module compares the measured period of the decoded radio composite signal with a reference period of the radio composite signal. For example, the error sensing module compares the measured frequency of the 19 KHz pilot tone with the known reference period of the 19 KHz pilot tone. These differences were illustrated in FIG. 5.

The processing then proceeds to Step 164 where the error sensing module is utilized by a feedback module to generate an error feedback signal based on a difference between the measured period and the reference period. For example, if the actual period of the pilot tone is measurable different from the reference pilot tone, the error sensing module generates an error feedback signal to indicate the phase and/or frequency difference between the measured period of the pilot tone and the reference period of the pilot tone.

FIG. 7 is a schematic block diagram of an embodiment of pilot tracking module 143 that describe error sensing module 144 and feedback module 145 in further detail. In this embodiment, error sensing module 144 includes a mixing module 170, a low pass filter (LPF) 172, and a comparator 174. Feedback module 145 includes a state variable filter 190, a summing module 192 and a Sigma Delta modulator 194. Mixing module 170 compares a digital reference period 178 (e.g., a 19 KHz tone to represent the reference pilot tone) with digital radio composite signal 158 received from the output of demodulation module 140 of FIG. 3. Mixing module 170, which may include a digital mixer, produces a mixed signal 180 (e.g., sin (ω₁t)*sin (ω₂t)=½ cos (ω₁−ω₂)t−½ cos (ω₁+ω₂)t, where ω₁ represent 2 π*f of the reference pilot tone and ω₂ represents 2 π*f of the measured pilot tone).

Low pass filter 172, which may be a multi-order CIC filter having a 2ⁿ down sampling factor, filters mixed signal 180 to produce a near-DC feedback error signal 182 (e.g., filters out the −½ cos(ω₁+ω₂)t term and passes the ½ cos(ω₁−ω₂)t term). A leaky bucket integrator may also be included to perform further filtering in order to create a filtered phase error correction signal that is supplied to detector/comparator 174. This filter function may set the clock recovery loop bandwidth.

Comparator 174 compares near DC feedback error signal 182 with a null signal or DC reference 184 to produce an offset 186 (e.g., determines the difference between ω₁ & ω₂ to produce the offset). Comparator 174 may also be described as comparing the carrier frequency of filtered signal 182 with DC to determine phase error. If the frequency of composite signal 158 matches the frequency of digital reference period 178, near DC feedback error signal 182 will have a zero frequency such that offset 186 will be zero. If, however, the frequency of composite signal 158 does not substantially match the frequency of digital reference period 178, near DC feedback error signal 182 will have a non-DC frequency. Offset 186 reflects the offset of the near DC error feedback signal from DC.

Further processing converts offset 186 into error feedback signal 154 as follows. State variable filter 190 filters offset 186 to produce a filtered offset 196. State variable filter 190 is analogous to a loop filter within a PLL that includes a resistive term and a capacitive term to integrate offset 186. The direct term included within the input to the state variable filter is analogous to the resistor in an analog PLL loop filter. An integration term within the input to the state variable filter is analogous to a large capacitor in an analog PLL loop filter. This state variable filter provides a memory element operable to store the correction output of detector/comparator 174.

The output of state variable filter 190 is provided to a first order sigma delta modulator 194 to quantize the correction into time intervals that may be implemented by an interpolator. A nominal sigma delta signal (i.e. estimated timing difference signal 198) may be combined with the output of the state variable filter with summing module 192 in order to provide the input to sigma delta modulator 194. Sigma delta modulator 194 provides a correction signal (i.e. feedback error signal) to interpolator or SRC in order to maintain and track the difference between the timing component within the received RF signal and the reference tone within the receiver.

Summing module 192 sums filtered offset 196 with a timing difference signal 198 to produce a summed signal 200. Timing difference signal 198 is a known timing difference signal such that filtered offset signal 196 represents only the unknown timing differences in the system due to such things that include process tolerance and temperature drift. Sigma Delta modulator 194 quantizes summed signal 200 to produce feedback error signal 154.

The decoder utilized within radio signal decoder IC 12, may also be utilized as a stand-alone decoder for decoding digitally encoded signals that are transmitted from a separate device. In such an embodiment, the decoder would include a SRC module, decoding module and error sensing module. The SRC module is operably coupled to convert, based on error feedback signal, the rate of an encoded signal from a first rate to a second rate to produce a rate adjusted encoded signal. The decoder may further include a sampling module. The sampling module receives an input signal and samples the signal at a given sampling rate to produce an encoded signal. The input signal may be a digital signal. In general, the decoder functions to receive the input signal, which is generated with respect to a first clock domain (e.g., the clock domain of the transmitter). The sampling module samples the input signal with a second clock domain (e.g., the clock domain of the receiver) and the SRC coverts the samples from the rate of the second clock domain to the rate of the first cock domain. The decoding module then processes the data at the rate of the first clock domain.

Linear SRC module converts digitally filtered signal into a sample rate adjusted digital signal based on a control feedback signal. This control feedback signal may be provided by the pilot tracking module as previously described. A linear interpolator may be implemented using linear SRC module and sigma-delta modulator. The linear SRC module is operably coupled to sample a digital signal in accordance with a control feedback signal. The sigma-delta modulator is operably coupled to produce the control feedback signal based on an interpolation ratio. In one embodiment, the interpolation ratio is a ratio between the input sample rate and the output sample rate of the linear interpolator.

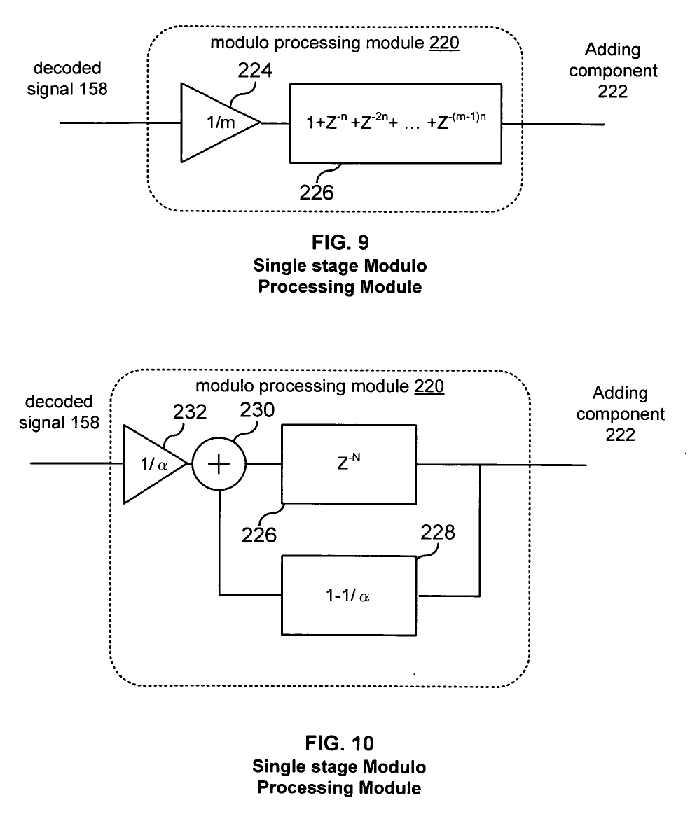

FIG. 8 is a schematic block diagram of a digital processing module that substantially performs the functions of a well defined notch filter. This processing module is operable to attenuate specific signal components within a digital data signal. However, this ability depends on the ability provided by the pilot tracking module to accurately track the pilot tones to be attenuated. Demodulator module 140 of FIG. 3 may provide a decoded digital radio composite signal 158. This digital processing module includes modulo processing module 220 and adding component 222. Modulo processing module 220 operates in a periodic fashion on every n^{th} sample of decoded digital radio composite signal 158. Specific embodiments of a Modulo processing module will be discussed with reference to FIGS. 9 through 11.

Modulo processing module 220 may be implemented as multi-tapped integrator, leaky bucket integrator, or other like known processing module. In this way, an accurate representation of the wave form of the specific signal components to be attenuated such as the pilot tones and their multiples of FIG. 4 may be generated. FIGS. 9 and 10 depict modulo processing module 220 as a single stage modulo processing module. In FIG. 9, modulo processing module 220 includes a scaling amplifier 224 and a Z^{-N} integrator 226. Scaling amplifier 224 is operable to apply a scaling factor α to decoded signal 158. Z^{-N} integrator 226 then operates in a periodic fashion on every n^{th} sample of the scaled decoded digital radio composite signal. By applying the scaling factor a prior to Z^{-N} integrator 226, greater stability and control over the output of the modulo processing module is realized.

Modulo processing module 220 of FIG. 10 includes a scaling factor block 228 and Z^{-N} integrator 226. As in FIG. 9, modulo processing module 220 produces a scaled output that is combined with the decoded signal 158. Here, scaling factor a may be applied as a feedback signal to Z^{-N} integrator 226. This scaling factor when applied through adding component 230 allows a properly scaled modulo processed signal to be produced which then may be subtracted from the decoded digital radio composite signal 158 with adding component 222. However, by applying the scaling factor a as a feedback signal, less stability and control over the output of the modulo processing module may be realized when compared to the modulo processing module of FIG. 9.

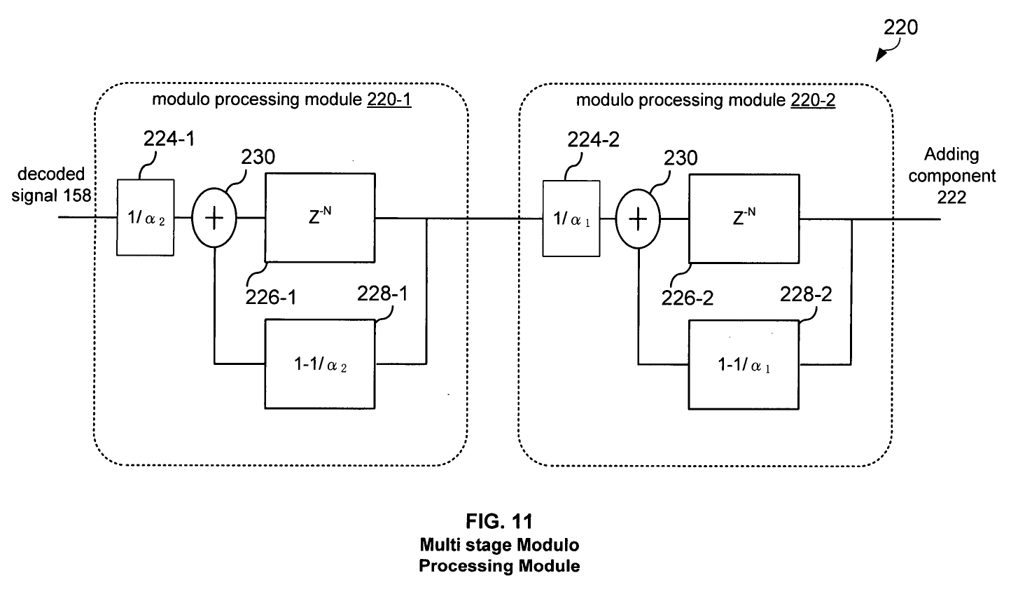

FIG. 11 is a schematic block diagram of a multi-stage digital processing module which uses two single stage modulo processing modules, first stage modulo processing module 220-1 and second stage modulo processing module 220-2, wherein each stage is a single stage modulo processing module such as the single stage modulo processing module illustrated in FIG. 9. These stages include scaling amplifiers 224-1 and 224-2 and a Z^{-N} integrators 226-1 and 226-2. The first stage 220-1 operates in a periodic fashion on every n^{th} sample of decoded digital radio composite signal 158. The second stage 220-2 operates in a periodic fashion on every n^{th} sample of the output of the first stage 220-1. Scaling factors, α₁ and α₂, are applied to the inputs of their respective modulo processing modules 220-1 and 220-2. This allows an even more precise estimation of the signal components (i.e. tones) to be canceled within digital radio composite signal 158. The individual stages function as the single stage shown in FIG. 9.

Although FIGS. 9, 10 and 11 depict only single stage and two stage modulo processing modules, the reader should appreciate that any arbitrary number of modulo processing modules may be used in combination within embodiments of the present invention. By using a digital processing module that includes a multi-tapped integrator or other like modulo processing operation module and scaling module, an excellent representation of the signal components to be attenuated may be used to filter these components from the received data signal. This results in a well defined filtered data signal.

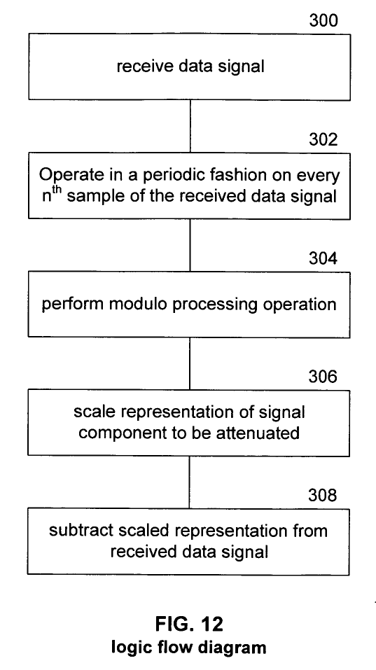

FIG. 12 provides a logic flow diagram illustrating a method for attenuating specific signal components within a data signal. Such data components may include timing components such as pilot tones and their multiples as seen within the composite signal of FIG. 4. This process first receives a decoded data signal in step 300. As shown in FIG. 8 this may be received from a decoding module or demodulator module such as demodulator 140 of FIG. 3. Step 302 operates in a periodic fashion on every n^{th} sample of the received data signal. A modulo processing operation, such as a multi-tapped integration, a leaky bucket integration, or other like averaging function on every n^{th} sample of the received data signal, is then performed in step 304 to produce a representation of the signal component to be attenuated. A scaling factor may be applied in step 306 to the representation before subtracting the representation of the signal component to be attenuated from the received data signal in step 308. Scaling is required because the signal components to be attenuated may lack predetermined amplitude or exhibit time varying amplitude. Subtracting the scaled representation of the signal component to be attenuated from the received data signal produces a filtered data signal in step 310 wherein the filtering process may exhibit a deep and well defined filter like function. This process requires that an exact phase lock exist. This is enabled by the pilot tracking module as previously discussed with reference to FIG. 7.

FIG. 13 provides a second logic flow diagram illustrating a method for attenuating specific signal components within a decoded composite FM signal. This logic flow diagram is similar to that of FIG. 10. However, in this instance the data signal is specifically identified as a decoded composite FM signal. Signal components to be attenuated may include timing components such as pilot tones and their multiples as seen within the composite signal of FIG. 4. This process first receives a decoded composite FM signal in step 310. Step 312 operates in a periodic fashion on every n^{th} sample of the received decoded composite FM signal. A modulo processing operation, such as a multi-tapped integration, a leaky bucket integration, or other like averaging function on every n^{th} sample of the received decoded composite FM signal, is then performed in step 314 to produce a representation of the signal component to be attenuated. A scaling factor may be applied in step 316 to the representation before subtracting the representation of the signal component to be attenuated from the received decoded composite FM signal in step 318. Scaling is required because the signal components to be attenuated may lack predetermined amplitude or exhibit time varying amplitude. Subtracting the scaled representation of the signal component to be attenuated from the received data signal produces a filtered data signal wherein the filtering process may exhibit a deep and well defined filter like function. The averaging function, filter complexity, group delay, and other like factors may affect the characteristics of this well defined filter like function.

In summary, the present invention provides a processing module or methodology that may be implemented within a handheld audio device for attenuating specific signal components within a digital data signal. Such data components may include timing components such as pilot tones and their multiples. A modulo processing operation, such as a multi-tapped integration, a leaky bucket integration, or other like averaging function is performed on every n^{th} sample of received data signals to produce a representation of the signal component to be attenuated. Scaling factors are then applied to the representation before subtracting the representation of the signal component to be attenuated from the received data signal. Subtracting the scaled representation of the signal component to be attenuated from the received data signal produces a filtered data signal wherein the process exhibits a deep and well defined filter.

As one of ordinary skill in the art will appreciate, the term “substantially” or “approximately”, as may be used herein, provides an industry-accepted tolerance to its corresponding term and/or relativity between items. Such an industry-accepted tolerance ranges from less than one percent to twenty percent and corresponds to, but is not limited to, component values, IC process variations, temperature variations, rise and fall times, and/or thermal noise. Such relativity between items ranges from a difference of a few percent to magnitude differences. As one of ordinary skill in the art will further appreciate, the term “operably coupled”, as may be used herein, includes direct coupling and indirect coupling via another component, element, circuit, or module where, for indirect coupling, the intervening component, element, circuit, or module does not modify the information of a signal but may adjust its current level, voltage level, and/or power level. As one of ordinary skill in the art will also appreciate, inferred coupling (i.e., where one element is coupled to another element by inference) includes direct and indirect coupling between two elements in the same manner as “operably coupled”. As one of ordinary skill in the art will further appreciate, the term “compares favorably”, as may be used herein, indicates that a comparison between two or more elements, items, signals, etc., provides a desired relationship. For example, when the desired relationship is that signal 1 has a greater magnitude than signal 2, a favorable comparison may be achieved when the magnitude of signal 1 is greater than that of signal 2 or when the magnitude of signal 2 is less than that of signal 1.

The preceding discussion has presented a handheld device that incorporates a radio signal decoder IC optimized interface with a digital audio processing IC. As one of average skill in the art will appreciate, other embodiments may be derived from the teaching of the present invention without deviating from the scope of the claims.

What is claimed is:

1. A method of attenuating specific signal components within a data signal, comprising:
receiving a data signal;
performing a multitap modulo processing operation in a periodic fashion on every N^{th} sample of the data signal to produce a multitapped modulo processed signal; and
subtracting the multitapped modulo processed signal from the received data signal to produce a filtered data signal.

2. The method of claim 1, wherein performing the multitap modulo processing operation in a periodic fashion on every N^{th} sample of the data signal to produce a multitapped modulo processed signal further comprises scaling the multitapped modulo processed signal.

3. The method of claim 1, wherein the specific signal components comprise:
a DC component;
a 19 kHz tone;
a 38 kHz tone;
a 57 kHz tone; and
a 76 kHz tone.

4. The method of claim 1, wherein the modulo processing operation comprises a modulo integration.

5. The method of claim 1, wherein the data signal comprises an FM composite signal.

6. The method of claim 1, wherein the specific signal component comprises a pilot tone or timing component.

7. The method of claim 6, further comprising establishing a phase lock to the pilot tone.

8. The method of claim 1, wherein the multitap modulo processing operation comprises averaging components of the received data signal.

9. A method of attenuating pilot tone(s) within a composite FM signal, comprising:
receiving a composite FM signal, wherein the composite FM signal comprises pilot tone(s);
performing a multitap modulo processing operation in a periodic fashion on every N^{th} sample of the composite FM signal to produce a multitapped modulo processed FM composite signal; and
subtracting the multitapped modulo processed FM composite signal from the composite FM signal to produce a filtered composite FM signal.

10. The method of claim 9, wherein performing the multitap modulo processing operation in a periodic fashion further comprises scaling the multitapped modulo processed FM composite signal.

11. The method of claim 9, wherein the pilot tone(s) comprise:
a DC component;
a 19 kHz tone;
a 38 kHz tone;
a 57 kHz tone; and
a 76 kHz tone.

12. The method of claim 9, wherein the modulo processing operation comprises a modulo integration.

13. The method of claim 9, wherein further comprising establishing a phase lock to the pilot tone(s).

14. The method of claim 9, wherein the multitap modulo processing operation comprises averaging components of the composite FM signal.

15. A signal component cancellation module operable to attenuate specific signal components within a received composite FM signal, comprising:
a modulo processing module operable to perform a multitap modulo processing operation in a periodic fashion on every N^{th} sample of the received composite FM signal in order to produce a multitapped modulo processed signal; and
a combiner operable to:
subtract the scaled multitapped modulo processed signal from the received composite FM signal; and
output a filtered composite FM signal.

16. The signal component cancellation module of claim 15, wherein the modulo processing module further comprises:
a scaling module operable to scale the multitapped modulo processed signal; and
an integration module operable to performing the multitap modulo processing operation.

17. The signal component cancellation module of claim 16, wherein the integration module comprises a leaky bucket integrator.

18. The signal component cancellation module of claim 15, wherein the composite FM signal is received from an FM demodulator.

19. The signal component cancellation module of claim 15, further comprising a droop correction module operable to droop correct the received composite FM signal.

20. The signal component cancellation module of claim 15, wherein the specific signal components comprise:
a DC component;
a 19 kHz tone;
a 38 kHz tone;
a 57 kHz tone; and
a 76 kHz tone.

21. The signal component cancellation module of claim 15, wherein the specific signal component comprises a pilot tone.

22. The signal component cancellation module of claim 17, wherein a phase lock is established with the pilot tone.

23. A signal component cancellation module operable to attenuate specific signal components within a received composite FM signal, comprising:
a first stage modulo processing module operable to perform a first multitap modulo processing operation in a periodic fashion on every N^{th} sample of the received composite FM signal in order to produce a first multitapped modulo processed signal;
a second stage modulo processing module operable to perform a second multitap modulo processing operation in a periodic fashion on every N^{th} sample of the first multitapped modulo processed signal in order to produce a second multitapped modulo processed signal; and
a combiner operable to:
subtract the second multitapped modulo processed signal from the received composite FM signal; and
output a filtered composite FM signal.

24. The signal component cancellation module of claim 23, wherein each modulo processing module further comprises:
a scaling module operable to scale the multitapped modulo processed signal; and
an integration module operable to performing the multitap modulo processing operation.
